(19) United States
(12) Patent Application Publication
(10) Pub. No.: US 2011/0014782 A1
(43) Pub. Date: Jan. 20, 2011

(54) Apparatus and Method for Growing a Microcrystalline Silicon Film

(75) Inventors: Shih-Cheng TSENG, Longtan Shiang (TW); Cheng-Chang Hsieh, Longtan Shiang (TW); Der-Jun Jan, Longtan Shiang (TW); Chi-Fong Ai, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL-INSTITUTE OF NUCLEAR ENERGY RESEARCH, Taoyuan (TW)

(21) Appl. No.: 12/390,433

(22) Filed: Feb. 21, 2009

(51) Int. Cl. H01L 21/20

(52) U.S. Cl. 438/488; 118/723 E; 257/E21.09

(57) ABSTRACT

Disclosed is a method for growing a microcrystalline silicon film on a substrate. The method includes the step of disposing the substrate in a chamber, the step of vacuuming the chamber and heating the substrate, the step of introducing reacting gas into the chamber as a precursor and keeping the pressure in the chamber at a predetermined value and the step of using RF energy in the chamber to dissociate the reacting gas to form plasma for growing the microcrystalline silicon film on the substrate. The reacting gas includes SiH₄/Ar mixture and H₂. The ratio of SiH₄/Ar mixture over H₂ is 1:1 to 1:20.

### FIELD OF INVENTION

The present invention relates to an apparatus and method for growing a microcrystalline silicon film and, more particularly, to an apparatus and method for growing a large microcrystalline silicon film by using a permanent magnet type helicon plasma source.

### BACKGROUND OF INVENTION

A lot of fossil fuel is consumed so that a lot of carbon dioxide is produced in accumulated in the atmosphere. Because of the green-house effect, the carbon dioxide in the atmosphere causes global warming. Global warming causes dramatic changes in the weather that are entailing unpredictable disasters.

There is a trend to use solar energy instead of fossil fuel. Solar energy is clean compared with fossil fuel. Based on the photoelectric effect, solar energy can be converted to electricity, without producing any carbon dioxide. Therefore, the green-house effect will be tremendously suppressed if the solar technology is mature and common. However, silicon is used in the semiconductor industry as well as in the solar industry. The demands for silicon are large and cause the prices of silicon to skyrocket. There is shortage of silicon in the solar industry so that the production of solar cells is affected. Hence, thin-film solar cells that require films of only a few micrometers thick seem to be the most promising solar cells.

There are tandem cells based on the combination of microcrystalline silicon with amorphous silicon. Tandem cells make use of a lot of solar energy since microcrystalline silicon and amorphous silicon absorb solar energy in different spectra. Microcrystalline silicon is derived from amorphous silicon. The structure of microcrystalline silicon is between the structure of amorphous silicon and the structure of crystalline silicon. Therefore, there are miniature silicon crystalline grains in the structure of microcrystalline silicon. Microcrystalline silicon exhibits several advantages. Firstly, it can easily be made into films. Secondly, the costs of processes for making films of microcrystalline silicon are low. Thirdly, it absorbs solar energy in a wide spectrum. Fourthly, it does not deteriorate easily. Fifthly, it provides high conversion efficiencies.

Disclosed in Taiwanese Patent No. 96122366 is a method for growing a microcrystalline silicon film on a substrate according to the plasma enhanced chemical vapor deposition (the “PECVD”). It however requires the H₂/SiH₄ ratio to be higher than 100. The consumption of H₂ is high. A lot of gas might be wasted.

A method for growing a microcrystalline silicon film on a substrate according to the chemical vapor deposition (the “CVD”) is disclosed in Taiwanese Patent No. 95142459. There is no need for a high H₂/SiH₄ ratio. However, the temperature of the substrate must be higher than 500 degrees Celsius. Hence, this conventional method is not common.

Therefore, the present invention is intended to obviate or at least alleviate the problems encountered in prior art.

### SUMMARY OF INVENTION

It is an objective of the present invention to provide a method and apparatus for growing a large microcrystalline film.

It is another objective of the present invention to provide a method and apparatus for growing a microcrystalline film without requiring a high H₂/SiH₄ ratio.

It is another objective of the present invention to provide a method and apparatus for growing a microcrystalline film on a substrate without having to heat the substrate to a high temperature.

To achieve the foregoing objectives, the method includes the step of disposing the substrate in a chamber, the step of vacuuming the chamber and heating the substrate, the step of introducing reacting gas into the chamber as a precursor and keeping the pressure in the chamber at a predetermined value and the step of using RF energy in the chamber to dissociate the reacting gas to form plasma for growing the microcrystalline silicon film on the substrate. The reacting gas includes SiH₄/Ar mixture and H₂. The ratio of SiH₄/Ar mixture over H₂ is 1:1 to 1:20.

Other objectives, advantages and features of the present invention will become apparent from the following description referring to the attached drawings.

### BRIEF DESCRIPTION OF DRAWINGS

The present invention will be described via the detailed illustration of the preferred embodiment referring to the drawings.

FIG. 1 is a flow chart of a method for growing a microcrystalline silicon film according to the preferred embodiment of the present invention.

FIG. 2 is a block diagram of an apparatus for executing the method shown in FIG. 1.

FIG. 3 is a Raman spectrum of the silicon crystalline grains of the microcrystalline silicon film made in the method shown in FIG. 1.

### DETAILED DESCRIPTION OF PREFERRED EMBODIMENT

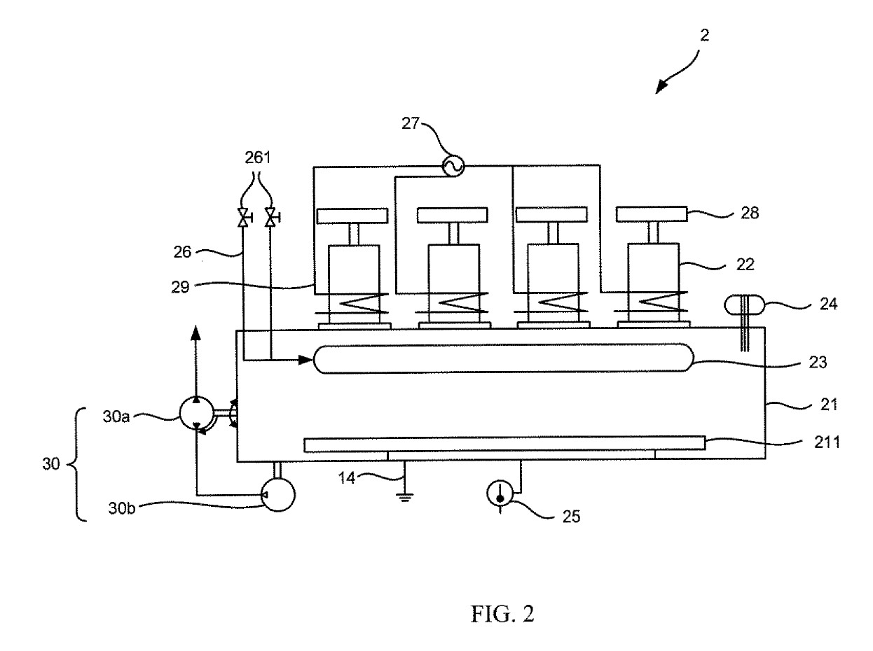

Referring to FIG. 2, there is shown an apparatus 2 for growing a microcrystalline silicon film on a substrate according to the preferred embodiment of the present invention. The apparatus 2 includes a chamber 21, helicon wave electrode tubes 22, a gas-distributing ring 23, a vacuum gauge 24, a heater 25, a gas pipe 26, a power supply 27, permanent magnets 28, a coil 29 and a pumping unit 30.

The chamber 21 is used to provide a low-pressure environment in which reaction is conducted. The pressure is lower than 10⁻³ torrs in the chamber 21 during the reaction. In the chamber 21 is a seat 211 for supporting the substrate.

Each of the helicon wave electrode tubes 22 includes an end connected to the chamber 21. An RF power supply is used to energize the helicon wave electrode tubes 22 to produce plasma. The helicon wave electrode tubes 22 are connected to one another to form an array to grow a large microcrystalline silicon film. Preferably, there are eight helicon wave electrode tubes 22, arranged in two rows of four. The distance between the rows is 18 cm. In each row, the distance between two adjacent helicon wave electrode tubes 22 is 18 cm.

The gas-distributing ring 23 is disposed in the chamber 21, beneath the helicon wave electrode tubes 22. The distance between the gas-distributing ring 23 and the substrate is about 10 to 30 cm. Reacting gas is introduced into the chamber 21 from the gas-distributing ring 23.

The vacuum gauge 24 is disposed in the chamber 21. The vacuum gauge 24 is used to measure the residual of the reacting gas in the chamber 21.

The heater 25 is located below the seat 211. The heater 25 is used to heat the substrate through the seat 211 to increase the temperature of the substrate to a predetermined point.

The gas pipe 26 includes a portion located outside the chamber 21 and a portion connected to the gas-distributing ring 23. The gas pipe 26 is provided with a pressure-controlling valve 261 operable to transfer the reacting gas to the gas-distributing ring 23 to regulate the pressure in the chamber 21.

The power supply 27 is located outside the chamber 21. The power supply 27 is connected to the helicon wave electrode tubes 22. The power supply 27 is used to provide RF energy to the reacting gas leaving the gas-distributing ring 23 so that the helicon wave electrode tubes 22 produce plasma.

The permanent magnets 28 are located outside the chamber 21. Each of the permanent magnets 28 is located near another end of a related one of the helicon wave electrode tubes 22. The permanent magnets 28 are used to produce a magnetic field to control a plasma field.

The coil 29 is located outside the chamber 21. The coil 29 is wound around each of the helicon wave electrode tubes 22 and connected to the power supply 27. Energized with the power supply 27, the coil 29 enhances the magnetic field to facilitate the dissociatation of the reacting gas into the plasma.

The pumping unit 30 is located outside the chamber 21. The pumping unit 30 includes a rough pump 30a connected to a fine pump 30b. The pumping unit 30 is used to pump air out of the chamber 21 to reduce the pressure in the chamber 21 to a predetermined point. A grounding terminal 31 is provided on an external side of the chamber 21.

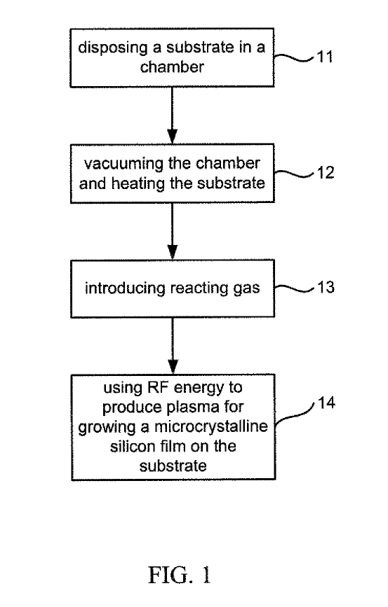

Shown in FIG. 1 is a method for growing a microcrystalline silicon film on a substrate according to the preferred embodiment of the present invention. The substrate may be a glass substrate, a silicon wafer or a steel substrate that can survive high temperature. For example, the substrate is a B270 glass substrate. The size of the substrate is at least 40 cm×40 cm. For example, the size of the substrate is 60 cm×60 cm×1 mm.

At 11, the substrate is disposed in the chamber 21. In detail, the substrate is located on the seat 211. The distance between the substrate and the gas-distributing ring 23 is about 18 cm.

At 12, the chamber 21 is vacuumed and the substrate is heated. In detail, the rough pump 30a is used to reduce the pressure in the chamber 21 to a value smaller than 10³ torrs. Then, the fine pump 30b is used to reduce the pressure in the chamber 21 to a point lower than le torrs. The heater 25 is used to increase the temperature of the substrate to a value between the room temperature and 400 degrees Celsius. Preferably, the temperature of the substrate is 200 degrees Celsius.

At 13, reacting gas is introduced into the chamber 21. In detail, the gas pipe 26 is opened to allow the reacting gas in the chamber 21. The reacting gas is used as a precursor. The reacting gas includes SiH₄/Ar mixture and H₂. The ratio of SiH₄/Ar mixture over H₂ is 1:1 to 1:20. Preferably, the ratio of SiH₄/Ar mixture over H₂ is 1:3. In the SiH₄/Ar mixture, the SiH₄/Ar ratio is 1:9. The pressure-controlling valve 261 is used to control the pressure in the chamber 21 to be between 1×10⁻³ and 1×10⁻² torrs.

At 14, RF energy is used to produce plasma to complete the growing of the microcrystalline silicon film. In detail, the power supply 27 is used to provide the chamber 21 with RF energy for 60 minutes. The power of the RF energy is 1000 to 8000 watts and, preferably, 4000 watts. The frequency of the RF energy is RF13.56 MHz. The RF energy is used to dissociate the reacting gas to produce plasma. The plasma is used to grow the microcrystalline silicon film on the substrate.

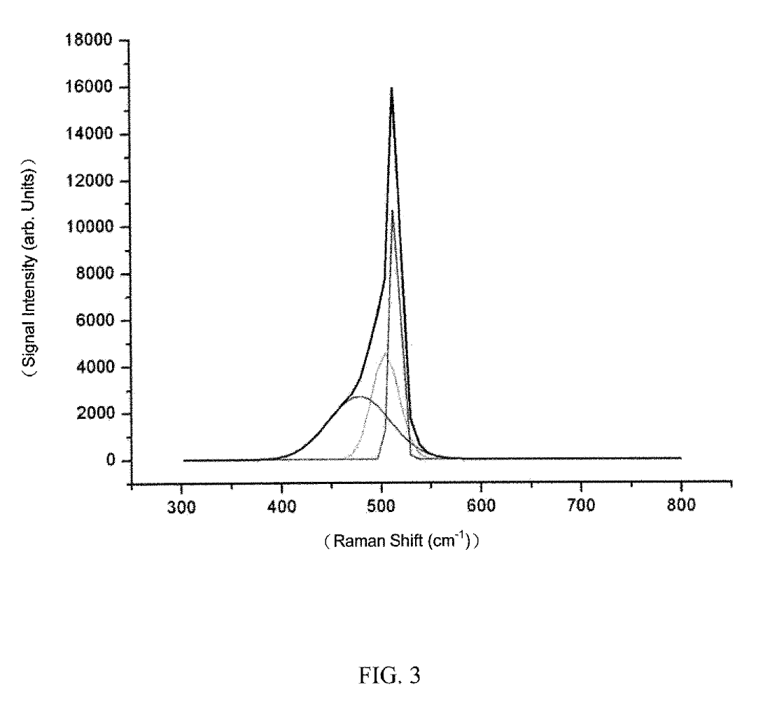

Referring to FIG. 3, a Raman spectrum of the silicon film is shown. The peak of the silicon film occurs at 508 cm⁻¹. Hence, it is determined that the silicon film is a microcrystalline silicon film, amorphous silicon dosed with crystalline silicon, because the peak of typical amorphous silicon occurs at 480 cm⁻¹ while the peak of typical crystalline silicon occurs at 520 cm⁻¹. 480 to 500 cm^{31 1} is an amorphous/crystalline transient range. Based on the peaks at 480 cm⁻¹, 500 cm⁻¹ and 520 cm⁻¹, a mathematic software program is used to calculate the crystallization ratio of the microcrystalline silicon film to be 58% according to the following formula:

(I500+I520)/(σI480+I500+I520)

As discussed above, the permanent magnet type helicon plasma is advantageously used in the present invention because the density thereof is high. Therefore, the H2/SiH4 ratio is low, and the method exhibits at least three advantages. Firstly, it is efficient. Secondly, it is conducted at a low temperature. Thirdly, it is used to grow a large microcrystalline silicon film.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A method for growing a microcrystalline silicon film on a substrate comprising the steps of:
disposing the substrate in a chamber;
vacuuming the chamber and, heating the substrate;
introducing reacting gas into the chamber as a precursor and keeping the pressure in the chamber at a predetermined value, wherein the reacting gas comprises SiH₄/Ar mixture and H₂, and the ratio of SiH₄/Ar mixture over H₂ is 1:1 to 1:20; and
using RF energy in the chamber to dissociate the reacting gas to form plasma for growing the microcrystalline silicon film on the substrate.

2. The method according to claim 1, wherein the substrate is selected from a group consisting of a glass substrate, a silicon wafer and a steel substrate.

3. The method according to claim 1, wherein the size of the substrate is at least 40 cm×40 cm.

4. The method according to claim 1, wherein the step of vacuuming the chamber and heating the substrate comprises the step of reducing the pressure in the chamber to a value smaller than 10⁻⁷ torrs.

5. The method according to claim 1, wherein the predetermined value of the temperature is the room temperature to 400 degrees Celsius.

6. The method according to claim 1, wherein the SiH₄/Ar ratio is 1:9.

7. The method according to claim 1, wherein the step of introducing the reacting gas into the chamber and keeping the pressure in the chamber at a predetermined value comprises the step of keeping the pressure in the chamber between 1×10⁻³ and 1×10⁻¹ torrs.

8. The method according to claim 1, wherein the power of the RF power supply is 1000 to 8000 watts.

9. The method according to claim 1, wherein the crystallization ratio of the microcrystalline silicon film is 50% to 90%.

10. An apparatus for growing a microcrystalline silicon film on a substrate comprising:
a chamber for providing an environment of lower than 10⁻³ torrs for reaction to take place therein, the chamber comprising a seat disposed therein for supporting the substrate.
helicon wave electrode tubes each comprising an end connected to the chamber for producing plasma;
a gas-distributing ring for introducing reacting gas into the chamber, wherein the gas-distributing ring is disposed in the chamber, beneath the helicon wave electrode tubes so that the distance between the gas-distributing ring and the substrate is about 10 to 30 cm;
a vacuum gauge for measuring the residual of the reacting gas in the chamber;
a heater located below the seat and used to heat the substrate through the seat to increase the temperature of the substrate to a predetermined point;
a gas pipe comprising a portion located outside the chamber, another portion connected to the gas-distributing ring and a pressure-controlling valve provided thereon and operable to transfer the reacting gas to the gas-distributing ring;
a power supply located outside the chamber, connected to the helicon wave electrode tubes and used to provide RF energy to the reacting gas leaving the gas-distributing ring so that the helicon wave electrode tubes produce plasma;
permanent magnets each located near another end of a related one of the helicon wave electrode tubes outside the chamber and used to produce a magnetic field to control a plasma field;
a coil wound around each of the helicon wave electrode tubes outside the chamber and connected to the power supply for enhancing the magnetic field to facilitate the dissociatation of the reacting gas into the plasma; and
a pumping unit located outside the chamber and used to pump air out of the chamber to reduce the pressure in the chamber to a predetermined point, wherein the pumping unit comprises a rough pump and a fine pump connected to the rough pump.

11. The apparatus according to claim 10, wherein the helicon wave electrode tubes are connected to one another and arranged in an array.

12. The apparatus according to claim 10, wherein the substrate is selected from a group consisting of a glass substrate, a silicon wafer and a steel substrate.

13. The apparatus according to claim 10, wherein the pressure-controlling valve is used to regulate the pressure in the chamber.

14. The apparatus according to claim 10, wherein the power supply provides the RF energy at RF13.56 MHz.

15. The apparatus according to claim 10 comprising a grounding terminal connected to the chamber.
